(19) United States
(12) Patent Application Publication
(10) Pub. No.: US 2026/0305191 A1
(43) Pub. Date: Oct. 1, 2026

(54) INTERMOLECULAR DE-BONDABLE WAFER BONDING FOR ADVANCED PACKAGING

(71) Applicant: Micron Technology, Inc., Boise, ID (US)

(72) Inventors: Chenxi Li, Boise, ID (US); Kyle K. Kirby, Eagle, ID (US)

(21) Appl. No.: 19/570,098

(22) Filed: Mar. 17, 2026

Related U.S. Application Data
(60) Provisional application No. 63/778,328, filed on Mar. 26, 2025.

(51) Int. Cl. H10P 10/00; H10P 56/00

(52) U.S. Cl. CPC H10P 10/14; H10P 56/00

(57) ABSTRACT

Intermolecular de-bondable wafer bonding for advanced packaging is disclosed herein. A method of preparing a device wafer includes bonding the device wafer to a carrier wafer, processing the device wafer, and debonding the device wafer from the carrier wafer. Bonding can include depositing first and second intermolecular bond (IMB) layers on the carrier wafer and the device wafer, respectively, and moving the carrier and/or device wafers toward one another such that the first and second IMB layers form an intermolecular bond therebetween. Debonding can include bringing a conductive material adjacent to at least one of the first IMB layer, the second IMB layer, or the device wafer, thereby weakening the intermolecular bond formed between the first IMB layer and the second IMB layer, and separating the first and second IMB layers from one another, thereby separating the device wafer from the carrier wafer.

### CROSS-REFERENCE TO RELATED APPLICATION(S)

The present application claims priority to U.S. Provisional Patent Application No. 63/778,328, filed Mar. 26, 2025, the disclosure of which is incorporated herein by reference in its entirety.

### TECHNICAL FIELD

The present technology generally relates to semiconductor devices, and more particularly relates to intermolecular de-bondable wafer bonding for advanced packaging.

### BACKGROUND

Microelectronic devices generally have a die (i.e., a chip) that includes integrated circuitry with a high density of very small components. Typically, dies include an array of very small bond pads electrically coupled to the integrated circuitry. The bond pads are external electrical contacts through which the supply voltage, signals, etc., are transmitted to and from the integrated circuitry. After dies are formed, they are “packaged” to couple the bond pads to a larger array of electrical terminals that can be more easily coupled to the various power supply lines, signal lines, and ground lines. Conventional processes for packaging dies include electrically coupling the bond pads on the dies to an array of leads, ball pads, or other types of electrical terminals, and encapsulating the dies to protect them from environmental factors (e.g., moisture, particulates, static electricity, and physical impact).

### BRIEF DESCRIPTION OF THE DRAWINGS

Features, aspects, and advantages of the presently disclosed technology may be better understood with regard to the following drawings.

FIG. 1 is a schematic side view of a device wafer temporarily bonded to a carrier wafer.

FIGS. 2A-2E illustrate bonding a device wafer to a carrier wafer in accordance with embodiments of the present technology.

FIGS. 3A-3D illustrate debonding a device wafer from a carrier wafer in accordance with embodiments of the present technology.

FIG. 4 is a flowchart illustrating a method of preparing a device wafer in accordance with embodiments of the present technology.

A person skilled in the relevant art will understand that the features shown in the drawings are for purposes of illustrations, and variations, including different and/or additional features and arrangements thereof, are possible.

### DETAILED DESCRIPTION

### I. Overview

Embodiments of the present technology are directed to forming intermolecular de-bondable wafer bonding with carrier wafers. Carrier wafers are used in semiconductor manufacturing to provide mechanical support and stability to device wafers during various fabrication processes. Device wafers, especially when thinned to very small thicknesses, can become fragile and difficult to handle. This fragility poses significant risks during processes such as thinning, etching, and high-temperature treatments, where mechanical stress or thermal expansion can lead to wafer breakage or warping. By temporarily bonding the device wafer to a more robust carrier wafer, manufacturers can ensure that the device wafer remains intact and properly aligned throughout these critical steps. The carrier wafer acts as a stabilizing platform, allowing for precise and controlled processing while minimizing the risk of damage.

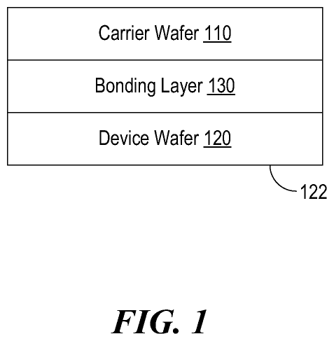

To illustrate, FIG. 1 is a schematic side view of a device wafer 120 temporarily bonded to a carrier wafer 110. The carrier wafer 110 can be composed silicon, glass, or other suitable material. The device wafer 120 can be a CMOS wafer, an array wafer (e.g., DRAM, NAND), and/or the like. As shown, the carrier wafer 110 and the device wafer 120 can be temporarily bonded to one another via a bonding layer 130 disposed therebetween. While bonded as shown, the device wafer 120 can be processed at a side 122 of the device wafer 120 opposite the bonding layer 130. Subsequently, the device wafer 120 can be separated from the carrier wafer 110 by at least partially destroying the bonding layer 130, such as via wet chemical etching, dry etching (plasma etching), thermal decomposition, and/or the like.

Many existing techniques for bonding and debonding the carrier wafer 110 and the device wafer 120, however, can often compromise the integrity of the device wafer 120. For example, in cases in which the bonding layer 130 includes an adhesive or other soft bonding material, the bonding layer 130 may not provide proper bonding due to, for example, thermal impacts. The bonding layer 130 may also cause misalignment and/or edge extrusion between the carrier wafer 110 and the device wafer 120 during the thermal bonding process due to, for example, the poor mechanical support provided by and the viscous nature of the bonding layer 130. The use of a soft bonding material can also lead to issues during debonding. For example, the solvent dissolution step may not adequately remove the adhesive, resulting in adhesive residues on the device wafer 120 and, consequently, the device wafer 120 failing to meet specifications. Also, mechanical sliding can be performed after decomposing the adhesive to separate the device wafer 120 from the carrier wafer 110, but doing so can damage the device wafer 120 (e.g., can damage the embedded structures thereof).

Alternatively, the bonding layer 130 can include silicon dioxide or other hard bonding material, but the use of such materials can also lead to issues. For example, the silicon dioxide may be gradually subjected to failure with elevated temperatures (e.g., temperatures above 400° C.). Also, due to void formation in such materials, the mechanical support provided may not be sufficient to withstand certain processing steps. The use of a hard bonding material can also be more time-consuming and costly compared to alternatives. Furthermore, in cases in which the carrier wafer 110 is composed of glass or other transparent (or translucent) material, laser can be used to de-bond the device wafer 120 from the carrier wafer 110, but laser debonding can be time-consuming and cost-inefficient.

Embodiments of the present technology address at least some of the above described issues associated with temporarily bonding device wafers to carrier wafers. For example, embodiments of the present technology are directed to forming an intermolecular bond to releasably secure a device wafer to a carrier wafer. In some embodiments, a method of preparing a device wafer includes (a) bonding the device wafer to a carrier wafer, (b) processing the device wafer, and (c) debonding the device wafer from the carrier wafer. Bonding the device wafer to the carrier wafer can include (i) depositing a first intermolecular bond (IMB) layer on the carrier wafer, (ii) depositing a second IMB layer on the device wafer, and (iii) moving the carrier wafer and/or the device wafer toward one another such that the first IMB layer and the second IMB layer form an intermolecular bond therebetween. Debonding the device wafer from the carrier wafer can include (i) bringing a conductive material adjacent to at least one of the first IMB layer, the second IMB layer, or the device wafer, thereby weakening the intermolecular bond formed between the first IMB layer and the second IMB layer, and (ii) separating the first IMB layer and the second IMB layer from one another, thereby separating the device wafer from the carrier wafer.

In some embodiments, a wafer bonding system includes a carrier wafer, a first IMB layer, a device wafer, a second IMB layer, and a conductive material. The first IMB layer and the second IMB layer can be configured to be deposited on the carrier wafer and the device wafer, respectively. When the first IMB layer and the second IMB layer are positioned adjacent to one another, the first IMB layer and the second IMB layer can form an intermolecular bond therebetween. The conductive material can be configured to, when positioned adjacent to at least one of the first IMB layer, the second IMB layer, or the device wafer, weaken the intermolecular bond formed between the first IMB layer and the second IMB layer.

Embodiments of the present technology enable bonding and debonding a device wafer and a carrier wafer with fewer steps (and thus faster and/or cheaper), greater flexibility in debonding (e.g., offering multiple debonding options), high thermal stability, robust mechanical support, and controllable alignment compared to existing bonding and debonding techniques. The embodiments disclosed herein also avoid the use of, and thus the disadvantages associated with, laser-based debonding. Also, the carrier wafer can be re-used and the resulting device wafer can be substantially damage-free and adhesive-free.

In the Figures, identical reference numbers identify generally similar, and/or identical, elements. Many of the details, dimensions, and other features shown in the Figures are merely illustrative of particular embodiments of the disclosed technology. Accordingly, other embodiments can have other details, dimensions, and features without departing from the spirit or scope of the disclosure. In addition, those of ordinary skill in the art will appreciate that further embodiments of the various disclosed technologies can be practiced without several of the details described below.

### II. Select Embodiments of Intermolecular Bonding and Debonding

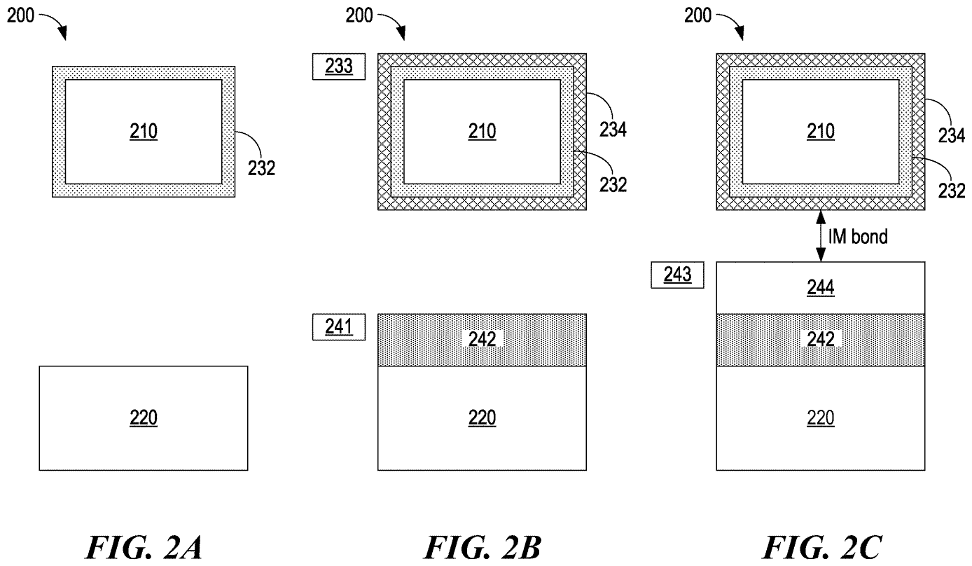

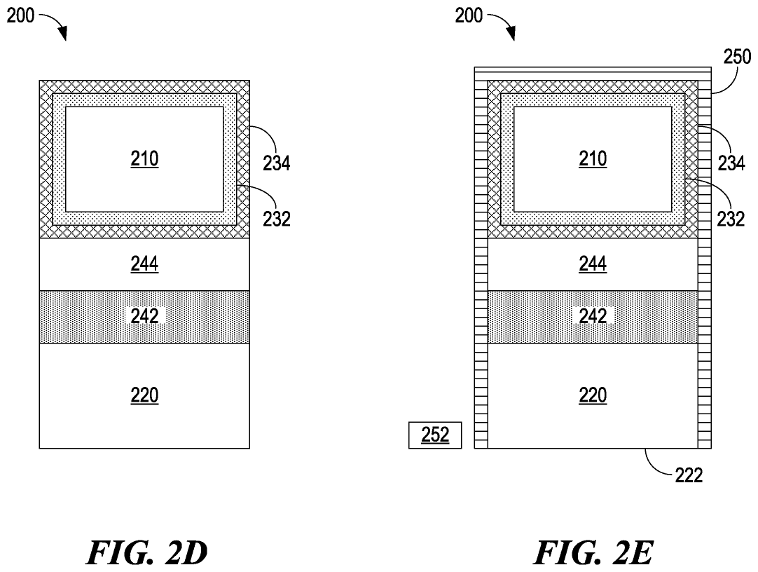

FIGS. 2A-2E illustrate bonding a device wafer 220 to a carrier wafer 210 in accordance with embodiments of the present technology. Referring first to FIG. 2A, a wafer bonding system 200 includes the carrier wafer 210 (e.g., silicon, glass) and the device wafer 220 (e.g., a CMOS wafer, an array wafer) not yet bonded to the carrier wafer 210. As shown, a thermal oxide layer 232 (e.g., silicon dioxide) can be formed on the carrier wafer 210. The thermal oxide layer 232 can partially or fully surround the carrier wafer 210.

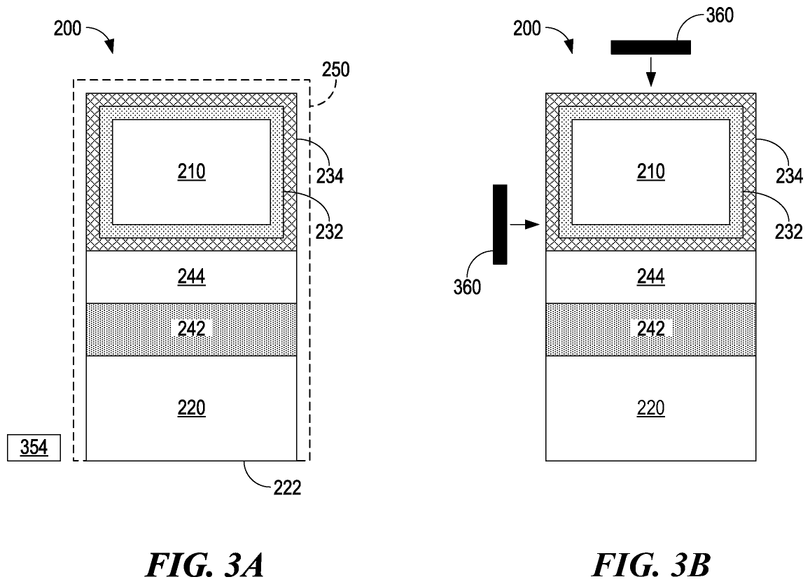

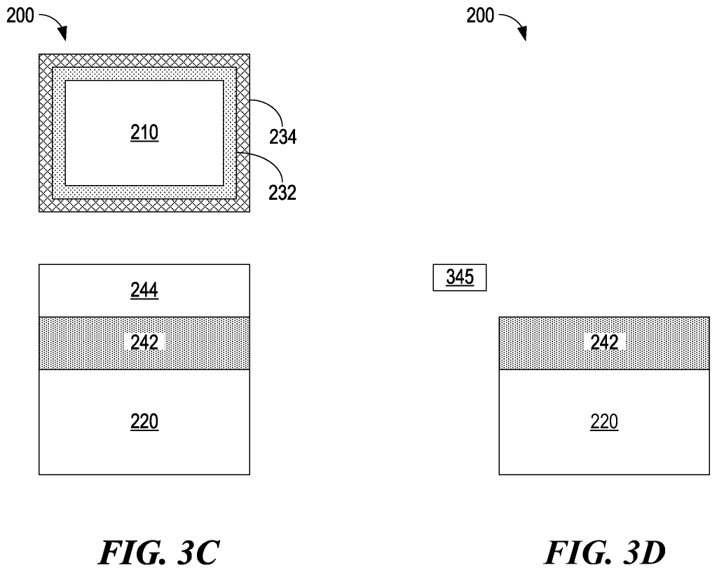

Referring next to FIG. 2B, a first intermolecular bond (IMB) layer 234 can be formed on the carrier wafer 210 and/or the thermal oxide layer 232. The first IMB layer 234 can partially or fully surround the carrier wafer 210 and/or the thermal oxide layer 232. In some embodiments, the wafer bonding system 200 also includes a first deposition tool 233 that can deposit the first IMB layer 234 via sputtering, physical vapor deposition (PVD), chemical vapor deposition (CVD), and/or the like. The first IMB layer 234 is discussed in greater detail below with reference to FIG. 2C. Also, an etch stop layer 242 can be formed on one side of the device wafer 220. The etch stop layer 242 can include silicon carbon nitride (SiCN) and/or other suitable material. In some embodiments, the wafer bonding system 200 also includes a second deposition tool 233 that can deposit the etch stop layer 242 on the device wafer 220 using suitable techniques. In some embodiments, the exposed surface of the etch stop layer 242 is substantially hydrogenated. The etch stop layer 242 is discussed in greater detail below with reference to FIG. 3D.

Referring next to FIG. 2C, a second IMB layer 244 can be formed on the side of the etch stop layer 242 opposite the device wafer 220. Thus, the etch stop layer 242 can effectively serve as an adhesive layer between the second IMB layer 244 and the device wafer 220. In some embodiments, the wafer bonding system 200 also includes a third deposition tool 243 that can deposit the second IMB layer 244 on the etch stop layer 244 using suitable techniques. In some embodiments, the carrier wafer 210, the thermal oxide layer 232, and the first IMB layer 234 can be flipped upside down such that, for example, a planarized side of the first IMB layer 234 faces the second IMB layer 244.

The materials selected for the first IMB layer 234 and the second IMB layer 244 can be suitable for forming an intermolecular (IM) bond forms therebetween (e.g., electrostatic charge materials with opposite charges). In some embodiments, the first IMB layer 234 has a Lewis acid-like structure and can thus act as an electron acceptor. For example, the first IMB layer 234 can include metal cations (e.g., transition metal cations). The metal cations can have empty d-orbitals that can accept electron pairs from other molecules, thereby facilitating the formation of bonds. In some embodiments, the second IMB layer 244 has free, mobile electrons (e.g., from lone pairs, from delocalized π-electrons in an aromatic ring). Examples include materials with sp²-hybridized carbon atoms, such as those found in graphene or aromatic compounds like benzene. The delocalized π-electrons in these materials are highly mobile and can be donated to electron-deficient species, making them effective Lewis bases.

As an illustrative, non-limiting example, the first IMB layer 234 can include zinc oxide (ZnO) and the second IMB layer 244 can include sp²-C (e.g., graphitic-C, sp²-hybridized carbon atoms bonded to oxygen atoms (ox-sp²-C)). The ZnO can act as a Lewis acid due to the presence of Zn²⁺ ions with empty d-orbitals, which can accept electron pairs. The sp²-C can act as a Lewis base due to its delocalized π-electrons that are free and mobile. When ZnO and sp²-C are brought together, the Zn²⁺ ions can interact with the π-electrons from the sp²-C, forming IM bonds or other charge transfer complexes.

Referring next to FIG. 2D, the first IMB layer 234 is bonded to the second IMB layer 244 (e.g., via IM bonding). Thus, the device wafer 220 is bonded to the carrier wafer 210. In some embodiments, the IM bond between the first IMB layer 234 and the second IMB layer 244 can have a bonding energy above a threshold bonding energy needed for the device wafer 220 to remain securely bonded to the carrier wafer 210 during subsequent processing, back-grinding, thinning, high-temperature processing, and/or the like. The threshold bonding energy can be about 1.2 J/m². Thus, the IM bond between the first IMB layer 234 and the second IMB layer 244 can have a bonding energy of at least 1.2 J/m², 1.6 J/m², 2.0 J/m², or between 1.0-3.0 J/m² or between 1.2-2.0 J/m² or between 1.4-1.8 J/m² (e.g., 1.7 J/m²).

Referring next to FIG. 2E, an encapsulation layer 250 can be formed on the first IMB layer 234, the second IMB layer 244, the etch stop layer 242, and the device wafer 220. In the illustrated embodiment, the encapsulation layer 250 fully surrounds the exposed sides of the first IMB layer 234, the second IMB layer 244, and the etch stop layer 242, but only partially surrounds the device wafer 220 to leave a side 222 of the device wafer 220 opposite the etch stop layer 242 exposed. In some embodiments, the wafer bonding system 200 also includes a fourth deposition tool 252 that can deposit the encapsulation layer 250 using suitable techniques.

Subsequently, the device wafer 220 can undergo processing at the side 222 while bonded to the carrier wafer 210 via the IM bond between the first IMB layer 234 and the second IMB layer 244. The encapsulation layer 250 (e.g., a nitride layer) can provide mechanical protection and/or electrical isolation. For example, the encapsulation layer 250 can protect the first IMB layer 234, the second IMB layer 244, the etch stop layer 242, and/or other layers during processing of the device wafer 220 and/or the debonding process discussed in greater detail below with reference to FIGS. 3A-3D. As another example, the encapsulation layer 250 can help preserve the IM bond between the first IMB layer 234 and the second IMB layer 244 by electrically isolating the first IMB layer 234 and the second IMB layer 244, thereby preventing the transfer of charge elsewhere.

FIGS. 3A-3D illustrate debonding the device wafer 220 from the carrier wafer 210 in accordance with embodiments of the present technology. It is appreciated that the device wafer 220 can be de-bonded from the carrier wafer 210 according to FIGS. 3A-3D after (i) the device wafer 220 is bonded to the carrier wafer 210 according to FIGS. 2A-2E (or other suitable bonding steps) and (ii) the device wafer 220 undergoes processing, which are outside the scope of the present technology and thus not illustrated herein.

Referring first to FIG. 3A, the encapsulation layer 250 can be removed from the first IMB layer 234, the second IMB layer 244, the etch stop layer 242, and the device wafer 220. In some embodiments, the wafer bonding system 200 includes a first removal tool 354 that can remove the encapsulation layer 250 via etching or other suitable techniques.

Referring next to FIG. 3B, one or more conductive materials 360 (e.g., metal layers, metal pads, or other metallic components) can be positioned adjacent to and/or in contact with the first IMB layer 234 and/or the second IMB layer 244. The presence of the one or more conductive materials 360 can weaken the IM bond and effectively de-bond the first IMB layer 234 and the second IMB layer 244. For example, the one or more conductive materials 360 can draw in and/or release electrons from the d-orbitals of the first IMB layer 234 and/or from the electron-rich surface of the second IMB layer 244. Thus, the one or more conductive materials 360 can allow the device wafer 220 to become separated from the carrier wafer 210.

In some embodiments, as an alternative to the steps illustrated in FIGS. 3A and 3B, the device wafer 220 can become separated from the carrier wafer 210 via wet processing. While the encapsulation layer 250 remains on the first IMB layer 234, the second IMB layer 244, the etch stop layer 242, and the device wafer 220, a liquid with electrolytes or an otherwise conductive fluid can be applied to the side 222 of the device wafer 220. For example, the conductive fluid can be sprayed onto the side 222 of the device wafer 220 and/or the stack (and the encapsulation layer 250) can be at least partially immersed in the conductive fluid such that the side 222 of the device wafer 220 is exposed to the conductive fluid. The encapsulation layer 250 can protect the other layers of the stack such that substantially only the side 222 of the device wafer 220 comes into contact with the conductive fluid. Like the one or more conductive materials 360 (FIG. 3B), the conductive fluid can draw in and/or release electrons and thereby de-bond the first IMB layer 234 and the second IMB layer 244. The encapsulation layer 250 can be subsequently removed (e.g., via etching). In some embodiments, the wet processing is performed after the encapsulation layer 250 is removed (e.g., after the step illustrated in FIG. 3A).

Referring next to FIG. 3C, the first IMB layer 234 and the second IMB layer 244 are shown separated from one another, and thus the device wafer 220 is de-bonded from the carrier wafer 210. Notably, none of the carrier wafer 210, the thermal oxide layer 232, the first IMB layer 234, the device wafer 220, the etch stop layer 242, or the second IMB layer 244 is destroyed or otherwise damaged. Rather, the thermal oxide layer 232 and the first IMB layer 234 remain on the carrier wafer 210, and the etch stop layer 242 and the second IMB layer 244 remain on the device wafer 220. Accordingly, the carrier wafer 210 can be re-used with another device wafer. In particular, in some cases, the carrier wafer 210, the thermal oxide layer 232, and the first IMB layer 234 can be re-used altogether without, for example, removing and re-applying the thermal oxide layer 232 and/or the first IMB layer 234.

Referring next to FIG. 3D, the second IMB layer 244 can be removed. In some embodiments, the wafer bonding system 200 includes a second removal tool 345 that can remove the second IMB layer 244 via oxygen plasma etching, chemical mechanical planarization (CMP), wet processing, or other suitable techniques. The etch stop layer 242 can protect the device wafer 220 from damage during removal of the second IMB layer 244. In some embodiments, the removal of the second IMB layer 244 leaves residue (e.g., of the second IMB layer 244) and/or an oxidized surface layer on the etch stop layer 242. In particular, the oxidized surface of the etch stop layer 242 can have a topography with increased roughness. Subsequently, the device wafer 220 (e.g., with the etch stop layer 242 remaining thereon) can undergo further processing, packaging, and/or assembly.

Referring to FIGS. 2A-3D together, embodiments of the present technology are expected to enable bonding and debonding a device wafer and a carrier wafer with fewer steps (and thus faster and/or cheaper), greater flexibility in debonding (e.g., offering multiple debonding options), high thermal stability, robust mechanical support, and controllable alignment compared to existing bonding and debonding techniques. The embodiments disclosed herein also avoid the use of, and thus the disadvantages associated with, laser-based debonding. And as previously discussed, the carrier wafer can be re-used and the resulting device wafer can be substantially damage-free and adhesive-free.

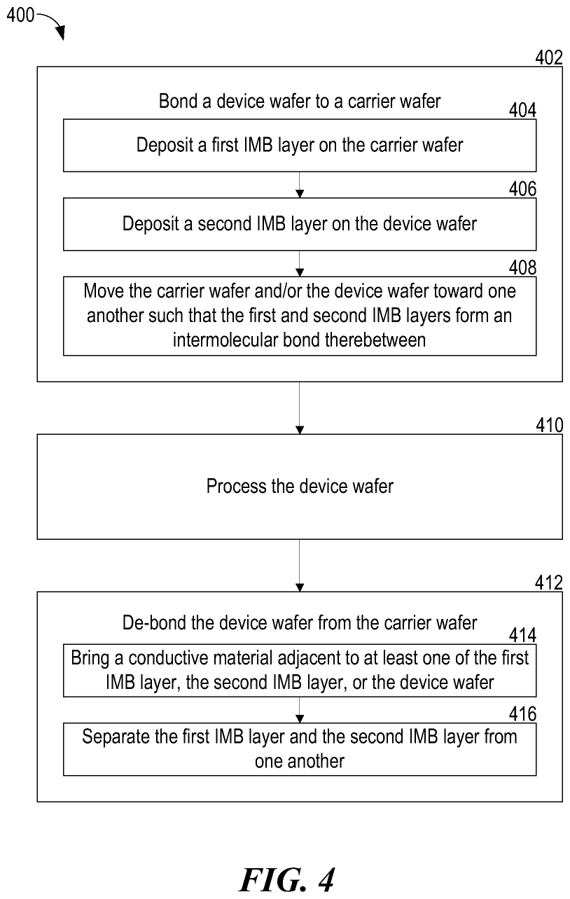

FIG. 4 is a flowchart illustrating a method 400 of preparing a device wafer in accordance with embodiments of the present technology. While the steps of the method 400 are described below in a particular order, one or more of the steps can be performed in a different order or omitted, and the method 400 can include additional and/or alternative steps. Additionally, although the method 400 may be described below with reference to the embodiments of the present technology described herein, the method 400 can be performed with other embodiments of the present technology.

The method 400 begins at block 402 by bonding a device wafer (e.g., the device wafer 220) to a carrier wafer (e.g., the carrier wafer 210). Bonding the device wafer to the carrier wafer can include blocks 404-408. At block 404, the method 400 continues by depositing a first IMB layer (e.g., the first IMB layer 234) on the carrier wafer. At block 406, the method 400 continues by depositing a second IMB layer (e.g., the second IMB layer 244) on the device wafer. At block 408, the method 400 continues by moving the carrier wafer and/or the device wafer toward one another such that the first IMB layer and the second IMB layer form an intermolecular bond therebetween.

In some embodiments, bonding the device wafer to the carrier wafer (block 402) further includes depositing an encapsulation layer (e.g., the encapsulation layer 250) on the first IMB layer, the second IMB layer, and the device wafer. The encapsulation layer may be deposited such that a side of the device wafer opposite the second IMB layer remains exposed. In some embodiments, bonding the device wafer to the carrier wafer (block 402) further includes depositing an etch stop layer (e.g., the etch stop layer 242) on the device wafer. In particular, the second IMB layer can be deposited on the etch stop layer such that the etch stop layer is positioned between the device wafer and the second IMB layer.

At block 410, the method 400 continues by processing the device wafer. In some embodiments, the device wafer is processed at the side of the device wafer opposite the second IMB layer, which may remain exposed even with the encapsulation layer deposited.

At block 412, the method 400 continues by debonding the device wafer from the carrier wafer. Debonding the device wafer from the carrier wafer can include blocks 414 and 416. At block 414, the method 400 continues by bringing a conductive material adjacent to at least one of the first IMB layer, the second IMB layer, or the device wafer. Bringing the conductive material can weaken the intermolecular bond formed between the first IMB layer and the second IMB layer. At block 416, the method 400 continues by separating the first IMB layer and the second IMB layer from one another, thereby separating the device wafer from the carrier wafer.

In some embodiments, debonding the device wafer from the carrier wafer (block 412) further includes removing the encapsulation layer from the first IMB layer, the second IMB layer, and the device wafer. In some embodiments, debonding the device wafer from the carrier wafer (block 412) further includes removing the second IMB layer from the etch stop layer while the etch stop layer protects the device wafer. The etch stop layer can have a first roughness when deposited on the device wafer, and a second roughness greater than the first roughness after the second IMB layer is removed from the etch stop layer.

Referring to FIGS. 2A-4 together, it is appreciated that the illustrated embodiments and the descriptions provided herein are merely examples, and that variations are within the scope of the present technology. For example, the example materials provided for the first IMB layer 234 can be used as the second IMB layer 244, and vice versa. As another example, while FIGS. 2A-3D illustrate a single device wafer bonded to and de-bonded from a carrier wafer, multiple device wafers can be bonded to and de-bonded from the carrier wafer (e.g., in parallel such that multiple second IMB layers are bonded to the same first IMB layer, in series such that the multiple device wafers are stacked together).

Although in the foregoing examples, the formation of IMBs has been described with reference to Lewis acid/base pairs, in other embodiments IMBs may be formed with charge-based, electrostatic-based, polarization-based, dipole-based, and/or work-function-driven intermolecular interactions. Further, although in the foregoing examples, the process of conductive debonding has been described with reference to conductive materials, in other embodiments conductive debonding may be accomplished or assisted through the application of electric fields, bias voltages, grounding, and/or induced conductivity, such that charge redistribution may be passive or actively applied. Moreover, conductive debonding may, in some embodiments, involve one-side debonding approaches (in which conductivity is introduced from only one side of a bonded pair), include remote or non-contact conductive interactions, and/or include transient or localized conductive exposure.

### III. Conclusion

It will be apparent to those having skill in the art that changes may be made to the details of the above-described embodiments without departing from the underlying principles of the present disclosure. In some cases, well known structures and functions have not been shown or described in detail to avoid unnecessarily obscuring the description of the embodiments of the present technology. Although steps of methods may be presented herein in a particular order, alternative embodiments may perform the steps in a different order. Similarly, certain aspects of the present technology disclosed in the context of particular embodiments can be combined or eliminated in other embodiments. Furthermore, while advantages associated with certain embodiments of the present technology may have been disclosed in the context of those embodiments, other embodiments can also exhibit such advantages, and not all embodiments need necessarily exhibit such advantages or other advantages disclosed herein to fall within the scope of the technology. Accordingly, the disclosure and associated technology can encompass other embodiments not expressly shown or described herein, and the invention is not limited except as by the appended claims.

Where the context permits, singular or plural terms may also include the plural or singular term, respectively. For example, throughout this disclosure, the singular terms “a,” “an,” and “the” include plural referents unless the context clearly indicates otherwise. Moreover, unless the word “or” is expressly limited to mean only a single item exclusive from the other items in reference to a list of two or more items, then the use of “or” in such a list is to be interpreted as including (a) any single item in the list, (b) all of the items in the list, or (c) any combination of the items in the list. Furthermore, as used herein, the phrase “and/or” as in “A and/or B” refers to A alone, B alone, and both A and B. Additionally, the terms “comprising,” “including,” “having,” and “with” are used throughout to mean including at least the recited feature(s) such that any greater number of the same features and/or additional types of other features are not precluded. Moreover, as used herein, the phrases “based on,” “depends on,” “as a result of,” and “in response to” shall not be construed as a reference to a closed set of conditions. For example, a step that is described as “based on condition A” may be based on both condition A and condition B without departing from the scope of the present disclosure. In other words, as used herein, the phrase “based on” shall be construed in the same manner as the phrase “based at least in part on” or the phrase “based at least partially on.”

Reference herein to “one embodiment,” “an embodiment,” “some embodiments” or similar formulations means that a particular feature, structure, operation, or characteristic described in connection with the embodiment can be included in at least one embodiment of the present technology. Thus, the appearances of such phrases or formulations herein are not necessarily all referring to the same embodiment. Furthermore, various particular features, structures, operations, or characteristics may be combined in any suitable manner in one or more embodiments.

Unless otherwise indicated, all numbers expressing numerical values used in the specification and claims, are to be understood as being modified in all instances by the term “about.” Accordingly, unless indicated to the contrary, the numerical parameters set forth in the specification and attached claims are approximations that may vary depending upon the desired properties sought to be obtained by the present technology. At the very least, and not as an attempt to limit the application of the doctrine of equivalents to the scope of the claims, each numerical parameter should at least be construed in light of the number of reported significant digits and by applying ordinary rounding techniques. The terms “about,” “approximately,” and “substantially” as used herein shall be interpreted to mean within ±10% of the stated value. Additionally, all ranges disclosed herein are to be understood to encompass the endpoints, and any and all subranges subsumed therein. For example, a range of “1 to 10” includes any and all subranges between (and including) the minimum value of 1 and the maximum value of 10 (e.g., any and all subranges having a minimum value of equal to or greater than 1 and a maximum value of equal to or less than 10, such as 5.5 to 10).

The disclosure set forth above is not to be interpreted as reflecting an intention that any claim or example requires more features than those expressly recited in that claim or example. Rather, as the preceding examples and the following claims reflect, inventive aspects lie in a combination of fewer than all features of any single foregoing disclosed embodiment. Thus, the preceding examples and the following claims are hereby expressly incorporated into the Detailed Description, with each claim standing on its own as a separate embodiment. This disclosure includes all permutations of the independent claims with their dependent claims.

What is claimed is:

1. A method of preparing a device wafer, comprising:
bonding the device wafer to a carrier wafer, wherein bonding comprises:
depositing a first intermolecular bond (IMB) layer on the carrier wafer,
depositing a second IMB layer on the device wafer, and
moving the carrier wafer and/or the device wafer toward one another such that the first IMB layer and the second IMB layer form an intermolecular bond therebetween;
processing the device wafer; and
debonding the device wafer from the carrier wafer, wherein debonding comprises:
bringing a conductive material adjacent to at least one of the first IMB layer, the second IMB layer, or the device wafer, thereby weakening the intermolecular bond formed between the first IMB layer and the second IMB layer, and
separating the first IMB layer and the second IMB layer from one another, thereby separating the device wafer from the carrier wafer.

2. The method of claim 1, wherein the first IMB layer includes zinc oxide.

3. The method of claim 1, wherein the second IMB layer includes ox-sp²-C.

4. The method of claim 1, wherein the intermolecular bond formed between the first IMB layer and the second IMB layer has a bonding energy of at least 1.2 J/m².

5. The method of claim 1, wherein bonding further comprises depositing an encapsulation layer on the first IMB layer, the second IMB layer, and the device wafer, and wherein debonding further comprises removing the encapsulation layer from the first IMB layer, the second IMB layer, and the device wafer.

6. The method of claim 5, wherein the encapsulation layer is deposited such that a side of the device wafer opposite the second IMB layer remains exposed.

7. The method of claim 5, wherein the encapsulation layer includes nitride.

8. The method of claim 1, wherein bonding further comprises depositing an etch stop layer on the device wafer, wherein the second IMB layer is deposited on the etch stop layer such that the etch stop layer is positioned between the device wafer and the second IMB layer, and wherein debonding further comprises removing the second IMB layer from the etch stop layer while the etch stop layer protects the device wafer.

9. The method of claim 8, wherein the etch stop layer has a first roughness when deposited on the device wafer, and wherein the etch stop layer has a second roughness greater than the first roughness after the second IMB layer is removed from the etch stop layer.

10. The method of claim 1, wherein bringing the conductive material comprises positioning a metallic component adjacent to at least one of the first IMB layer or the second IMB layer.

11. The method of claim 1, wherein bringing the conductive material comprises spraying a conductive fluid onto a side of the device wafer opposite the second IMB layer.

12. The method of claim 1, wherein bringing the conductive material comprises at least partially immersing the device wafer in a conductive fluid such that a side of the device wafer opposite the second IMB layer contacts the conductive fluid.

13. A wafer bonding system, comprising:
a carrier wafer;
a first intermolecular bond (IMB) layer configured to be deposited on the carrier wafer;
a device wafer;
a second IMB layer configured to be deposited on the device wafer, wherein, when the first IMB layer and the second IMB layer are positioned adjacent to one another, the first IMB layer and the second IMB layer form an intermolecular bond therebetween; and
a conductive material configured to, when positioned adjacent to at least one of the first IMB layer, the second IMB layer, or the device wafer, weaken the intermolecular bond formed between the first IMB layer and the second IMB layer.

14. The wafer bonding system of claim 13, wherein the conductive material is configured to weaken the intermolecular bond by drawing in and/or releasing electrons from the first IMB layer and/or the second IMB layer.

15. The wafer bonding system of claim 13, wherein the first IMB layer includes a transition metal cation.

16. The wafer bonding system of claim 13, wherein the second IMB layer includes sp²-hybridized carbon.

17. The wafer bonding system of claim 13, wherein the intermolecular bond formed between the first IMB layer and the second IMB layer has a bonding energy of about 1.7 J/m².

18. The wafer bonding system of claim 13, further comprising a nitride encapsulation layer configured to be deposited on the first IMB layer, the second IMB layer, and the device wafer.

19. The wafer bonding system of claim 13, further comprising a thermal oxide layer surrounding the carrier wafer, wherein the first IMB layer surrounds the thermal oxide layer.

20. The wafer bonding system of claim 13, wherein the carrier wafer is configured to be reusable after the conductive material weakens the intermolecular bond and the first IMB layer separates from the second IMB layer.
